(19) United States
(12) Patent Application Publication
(10) Pub. No.: US 2012/0086462 A1
(43) Pub. Date: Apr. 12, 2012

(54) TEST APPARATUS

(75) Inventor: Masahiro Ishida, Tokyo (JP)

(73) Assignee: ADVANTEST CORPORATION, Tokyo (JP)

(21) Appl. No.: 13/268,243

(22) Filed: Oct. 7, 2011

(30) Foreign Application Priority Data
Oct. 12, 2010 (JP) 2010-229682

(51) Int. Cl. G01R 35/00

(52) U.S. Cl. 324/601

(57) ABSTRACT

A power supply compensation circuit generates a compensation pulse current when a switch element is turned on. A pattern generator generates a test pattern that specifies a test signal to be output from a driver and a control signal to be output from the driver. In a calibration step, a voltage measurement unit measures the power supply voltage. A current adjustment unit adjusts the compensation pulse current to be generated in a test step after the calibration step.

### BACKGROUND OF THE INVENTION

1. Field of the Invention

The present invention relates to a technique for stabilizing a power supply.

2. Description of the Related Art

In a testing operation for a semiconductor integrated circuit that employs CMOS (Complementary Metal Oxide Semiconductor) technology such as a CPU (Central Processing Unit), DSP (Digital Signal Processor), memory, or the like (which will be referred to as the “DUT” hereafter), electric current flows in a flip-flop or a latch included in the DUT while it operates receiving the supply of a clock. When the clock is stopped, the circuit enters a static state in which the amount of current decreases. Accordingly, the sum total of the operating current (load current) of the DUT changes over time depending on the content of the test operation, and so forth.

A power supply circuit configured to supply electric power to such a DUT has a configuration employing a regulator. Ideally, such a power supply circuit is capable of supplying constant electric power regardless of the load current. However, in actuality, such a power supply circuit has an output impedance that is not negligible. Furthermore, between the output circuit and the DUT, there is an impedance component that is not negligible. Accordingly, the power supply voltage fluctuates due to fluctuation in the load.

Fluctuation in the power supply voltage seriously affects the test margin for the DUT. Furthermore, such fluctuation in the power supply voltage affects the operations of other circuit blocks included in the test apparatus, such as a pattern generator configured to generate a pattern to be supplied to the DUT, a timing generator configured to control the pattern transition timing, etc., leading to deterioration in the test accuracy.

In order to solve such a problem, a technique has been proposed in which the power supply voltage is corrected according to a test pattern to be supplied to a DUT so as to stabilize the power supply voltage at the DUT terminal (Patent document 1).

### RELATED ART DOCUMENTS

### Patent Documents

[Patent document 1]
Japanese Patent Application Laid Open No. 2007-205813

With such a technique disclosed in Patent document 1, the power supply voltage is compensated for after the test pattern to be applied to the DUT is read out. Accordingly, there is a potential for failure to follow a sudden change in the power supply voltage, leading to a delay in the compensation for the power supply voltage according to the test pattern. Furthermore, the power supply compensation circuit is configured as part of the power supply circuit. Accordingly, the frequency band in which the compensation is effective is limited by the impedance between the power supply circuit and the DUT. In addition, such an arrangement requires a multi-bit D/A converter that corresponds to the amount of potential change in the power supply voltage to be compensated for and the resolution of the compensation.

### SUMMARY OF THE INVENTION

The present invention has been made in order to solve such a problem. Accordingly, it is a general purpose of the present invention to provide a test apparatus which is capable of compensating for fluctuation in the power supply voltage.

An embodiment of the present invention relates to a test apparatus configured to test a device under test. The test apparatus comprises a main power supply, a power supply compensation circuit, multiple drivers; multiple interface circuits, a pattern generator, a voltage measurement unit, and a current adjustment unit. The main power supply is configured to supply electric power to a power supply terminal of the device under test. The power supply compensation circuit comprises a switch element, and is configured to generate a compensation pulse current when the switch element is turned on, and to inject the compensation pulse current thus generated into the power supply terminal via a path that differs from that of the main power supply, and/or to draw the compensation pulse current from the power supply current that flows from the main power supply to the device under test via a path that differs from that of the device under test. One of the multiple drivers is assigned to the switch element. At least one other of the multiple drivers is assigned to at least one of the input/output terminals of the device under test. The interface circuits are provided to the respective drivers, each configured to shape an input pattern signal, and to output the pattern signal thus shaped to the corresponding driver. The pattern generator is configured to output a test pattern which specifies a test signal to be output from one driver assigned to the input/output terminal of the device under test to the interface circuit that corresponds to the driver. Furthermore, the pattern generator is configured to output a control pattern which specifies the control signal to be output from one driver assigned to the switch element to the interface circuit that corresponds to the driver. The control pattern is determined according to the test pattern. The voltage measurement unit is configured to measure the power supply voltage in a state in which the pattern generator outputs the test pattern and the control pattern in a calibration step executed for each device under test. The current adjustment unit is configured to adjust, for each device under test according to the power supply voltage measured for each device under test, the compensation pulse current to be generated in the test step after the calibration.

If the test pattern is known, the operating rate of the internal circuit of the device under test that is supplied with the test pattern can be estimated. Thus, the time waveform of the operating current of the device under test can be predicted. Furthermore, by determining the control pattern according to the predicted operating current, such an arrangement is capable of compensating for, by means of the compensation pulse current, the component that cannot be followed by the main power supply. Alternatively, a component that cannot be followed by the main power supply can be intentionally injected by means of the compensation pulse current. As a result, such an arrangement is capable of maintaining, at a constant level, the power supply voltage that develops at the power supply terminal. Alternatively, such an arrangement is capable of intentionally providing fluctuation in the power supply voltage, thereby emulating a desired power supply environment.

Here, the current that flows through the internal elements that compose the device under test changes due to process variation. That is to say, the waveform of the operating current of the device under test in a state in which it receives a given test pattern changes upward or downward due to process variation. Thus, by performing a calibration step before the test step for the device under test in order to adjust the compensation pulse current, such an arrangement is capable of maintaining the power supply environment at a constant level even if there is variation in the operating current of the device under test due to process variation.

With another embodiment, in a calibration step executed for each device under test, a voltage measurement unit measures the power supply voltage in a state in which the pattern generator outputs only a test pattern. A current adjustment unit adjusts, for each device under test, the compensation pulse current to be generated in the test step after the calibration according to the power supply voltage measured for each device under test.

If the impedance characteristics of the power supply are known, by measuring the change in the power supply voltage when only the test pattern is supplied, without supplying the control pattern, such an arrangement is capable of calculating the waveform of the power supply current including the effects of process variation. That is to say, such an arrangement is capable of calculating the process variation component of the operating current based upon the amount of change in the power supply voltage. Thus, such an arrangement is capable of correcting the compensation current based upon the process variation component of the operating current thus calculated.

It is to be noted that any arbitrary combination or rearrangement of the above-described structural components and so forth is effective as and encompassed by the present embodiments. Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a circuit diagram which shows a configuration of a test apparatus according to an embodiment;

FIG. 2 shows waveform diagrams showing examples of the operating current, power supply current, source compensation current, and source pulse current subjected to pulse width modulation; and

FIGS. 3A and 3B are diagrams showing a specific example configuration of a power supply compensation circuit.

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention.

In the present specification, a state represented by the phrase “the member A is connected to the member B” includes a state in which the member A is indirectly connected to the member B via another member that does not affect the electric connection therebetween, in addition to a state in which the member A is physically and directly connected to the member B. Similarly, a state represented by the phrase “the member C is provided between the member A and the member B” includes a state in which the member A is indirectly connected to the member C, or the member B is indirectly connected to the member C via another member that does not affect the electric connection therebetween, in addition to a state in which the member A is directly connected to the member C, or the member B is directly connected to the member C.

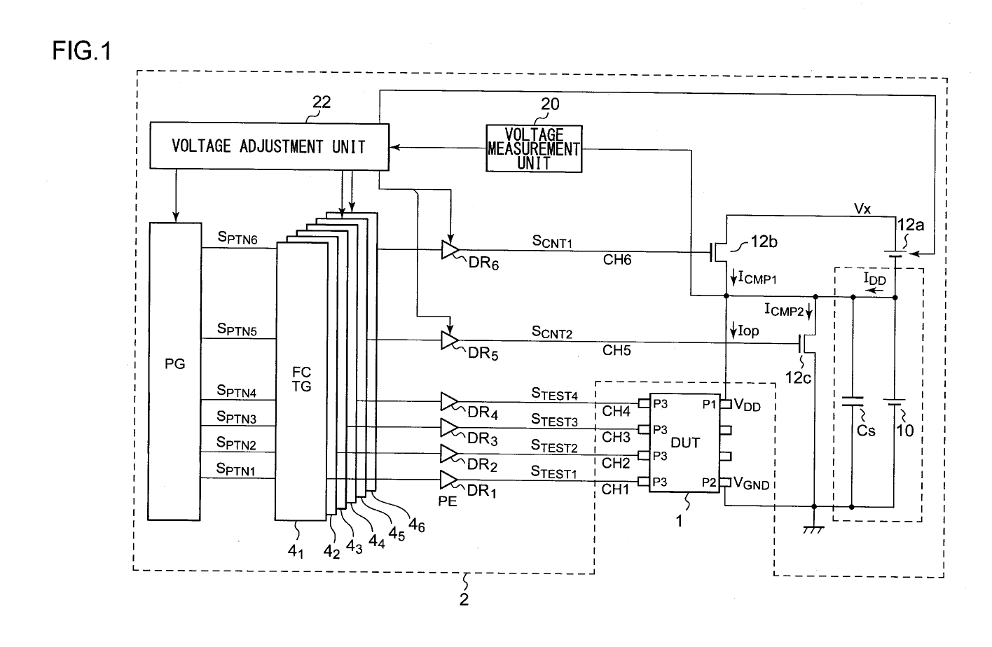

FIG. 1 is a circuit diagram which shows a configuration of a test apparatus 2 according to an embodiment. FIG. 1 shows a semiconductor device (which will be referred to as “DUT” hereafter) 1, in addition to the test apparatus 2.

The DUT 1 includes multiple pins. At least one of the multiple pins is a power supply terminal P1 configured to receive a power supply voltage V_{DD}, and at least one other pin is configured as a ground terminal P2. The multiple input/output (I/O) pins P3 are each configured to receive data from outside the circuit or to output data to outside the circuit. In the test operation, the multiple input/output terminals P3 receive a test signal (test pattern) S_{TEST} output from the test apparatus 2, or output data that corresponds to the test signal S_{TEST} to the test apparatus 2. FIG. 1 shows only a part of the configuration of the test apparatus 2, which is configured to supply a test signal to the DUT 1. That is to say, another configuration thereof configured to evaluate a signal received from the DUT 1 is not shown.

The test apparatus 2 includes a main power supply 10, a pattern generator PG, multiple timing generators TG, multiple waveform shapers FC, multiple drivers DR, a power supply compensation circuit 12, a voltage measurement unit 20, and a current adjustment unit 22.

The test apparatus 2 includes multiple channels, e.g., n channels CH1 through CHn, several channels (CH1 through CH4) of which are respectively assigned to the multiple I/O terminals P3 of the DUT 1. FIG. 1 shows an arrangement in which n=6. However, in practical use, the number of channels of the test apparatus 2 is on the order of several hundred to several thousand.

The main power supply 10 generates the power supply voltage V_{DD} to be supplied to the power supply terminal P1 of the DUT 1. For example, the main power supply 10 is configured as a linear regulator, a switching regulator, or the like, and performs feedback control such that the power supply voltage V_{DD} to be supplied to the power supply terminal P1 matches a target value. The capacitor Cs is provided in order to smooth the power supply voltage V_{DD}. The main power supply 10 is configured to generate a power supply voltage to be supplied to the DUT 1. In addition, the main power supply 10 is further configured to generate a power supply voltage to be supplied to the other circuit blocks included in the test apparatus 2. The output current flowing from the main power supply 10 to the power supply terminal P1 of the DUT 1 will be referred to as the “power supply current I_{DD}”.

The main power supply 10 is configured as a voltage/current source having a limited response speed. Accordingly, in some cases, the main power supply 10 cannot follow a sudden change in the load current, i.e., the operating current I_{OP} of the DUT 1. For example, when the operating current I_{OP} changes in a stepwise manner, overshoot or undershoot occurs in the power supply voltage V_{DD}, following which, in some cases, ringing occurs in the power supply voltage V_{DD}. Such fluctuation in the power supply voltage V_{DD} leads to difficulty in testing the DUT 1 with high precision. This is why, when an error is detected in the operation of the DUT 1, such an arrangement cannot judge whether such an error is due a manufacturing fault in the DUT 1 or due to the fluctuation in the power supply voltage V_{DD}.

The power supply compensation circuit 12 is provided in order to compensate for the response speed of the main power supply 10. The designer of the DUT 1 can estimate the change over time in the operating rate of an internal circuit of the DUT 1 when a known test signal S_{TEST} (test pattern S_{PTN}) is supplied to the DUT 1. Accordingly, the designer can predict the waveform of the operating current I_{OP} of the DUT 1 over time with high precision. Examples of such a prediction method include a calculation method using computer simulation, or an actual measurement method in which a device having the same configuration as that of the DUT 1 is measured. Such a prediction method is not restricted in particular.

Furthermore, in a case in which the response speed of the main power supply 10 (gain, feedback band) is known, the designer can also estimate the power supply current I_{DD} generated by the main power supply 10 according to the estimated operating current I_{OP}. In this case, by compensating for the difference between the estimated operating current I_{OP} and the estimated power supply current I_{DD} by means of the power supply compensation circuit 12, such an arrangement is capable of stabilizing the power supply voltage V_{DD}.

The power supply compensation circuit 12 includes an auxiliary power supply 12a, a source switch 12b, and a sink switch 12c. The source switch 12b and the sink switch 12c are each configured as a switch employing a MOSFET (Metal Oxide Semiconductor Field Effect Transistor), for example, and are configured to be controlled according to control signals S_{CNT1} and S_{CNT2}, respectively. The auxiliary power supply 12a may be a voltage source configured to generate a voltage that is higher than the power supply voltage V_{DD}, or may be a current source configured to generate a current that flows to the power supply terminal P1.

The source switch 12b is arranged between the output terminal of the auxiliary power supply 12a and the power supply terminal P1 of the DUT 1. When the source switch 12b is turned on according to the control signal S_{CNT1}, a compensation pulse current (which will also be referred to as the “source pulse current”) Is is generated. The power supply compensation circuit 12 injects the source pulse current I_{SRC} into the power supply terminal P1 via a path that differs from that of the main power supply 10. The sink switch 12c is arranged between another fixed voltage terminal (e.g., the ground terminal) and the power supply terminal P1 of the DUT 1. When the sink switch 12c is turned on according to the control signal S_{CNT2}, a compensation pulse current I_{SINK} (which will also be referred to as the “sink pulse current”) is generated. The power supply compensation circuit 12 draws, via a path that differs from that to the DUT 1, the sink pulse current I_{SINK} from the power supply current I_{DD} that flows to the power supply terminal P1.

With the current that flows to the power supply terminal P1 of the DUT 1 as the operating current I_{OP}, the following Expression (1) holds true based on the law of conservation of current.

I_{OP}=I_{DD}+I_{SRC}−I_{SINK} (1)

Among the drivers DR₁ through DR₆, the driver DR₆ is assigned to the source switch 12b, and the driver DR₅ is assigned to the sink switch 12c. Of the other drivers, e.g., the drivers DR₁ through DR₄, at least one is respectively assigned to at least one of the I/O terminals P3 of the DUT 1.

A pair comprising the waveform shaper FC and the timing generator TG is collectively referred to as an “interface circuit 4”. Multiple interface circuits 4₁ through 4₆ are respectively provided for the channels CH1 through CH6, i.e., for the drivers DR₁ through DR₆. The i-th (1≦i≦6) interface circuit 4ᵢ shapes the input pattern signal S_{PTNi} such that it has a signal format that is suitable for the driver DR, and outputs the pattern signal thus shaped to the corresponding driver DRᵢ.

The pattern generator PG generates the pattern signals S_{PTN1} through S_{PTN6} for the interface circuits 4₁ through 4₆ according to a test program. Specifically, with regard to the drivers DR₁ through DR₄ respectively assigned to the I/O terminals P3 of the DUT 1, the pattern generator PG outputs the test patterns S_{PTN1} through S_{PTN4}, each specifying a test signal S_{TESTi} to be generated by the corresponding driver DRᵢ, to the respective interface circuits 4ᵢ that correspond to the respective drivers DRᵢ. Each test pattern S_{PTNi} includes data which represents the signal level for each cycle (unit interval) of the test signal S_{TESTi}, and data which indicates the timing at which the signal level transits.

Furthermore, the pattern generator PG generates control patterns S_{PTN6} and S_{PTN5} which respectively specify the control signals S_{CNT1} and S_{CNT2} to be output from the drivers DR₆ and DR₅ respectively assigned to the source switch 12b and the sink switch 12c, and outputs the control patterns S_{PTN6} and S_{PTN5} thus generated to the respective interface circuits 4₆ and 4₅. The control patterns S_{PTN6} and S_{PTN5} respectively include data which specifies the on/off state of the source switch 12b for each cycle, and data which specifies the on/off state of the sink switch 12c for each cycle. Furthermore, the control patterns S_{PTN6} and S_{PTN5} respectively include data which specifies the timing at which the on/off state of the source switch 12b is to be switched, and data which specifies the timing at which the on/off state of the sink switch 12c is to be switched. The control patterns S_{PTN5} and S_{PTN6} are each determined according to the test patterns S_{PTN1} through S_{PTN4} such that the power supply voltage V_{DD} at the power supply terminal P1 is maintained at a constant level in a state in which the test signal S_{TEST} is supplied.

As described above, if the test patterns S_{PTN1} through S_{PTN4} are known, the waveform over time of the operating current I_{OP} of the DUT 1 can be estimated. Thus, the waveforms over time of the compensation currents I_{CMP1} and I_{CMP2}, which are to be generated in order to maintain the power supply voltage V_{DD} at a constant level, can be calculated.

When the estimated operating current I_{OP} is greater than the power supply current I_{DD}, the power supply compensation circuit 12 generates a source compensation current I_{CMP1} so as to compensate for a shortfall in the current. The current waveform that is required to generate such a source compensation current I_{CMP1} can be predicted. Thus, the source switch 12b is controlled so as to appropriately generate the source compensation current I_{CMP1}. For example, the source switch 12b may be controlled by pulse width modulation. Alternatively, pulse amplitude modulation, delta-sigma modulation, pulse density modulation, pulse frequency modulation, or the like, may be employed.

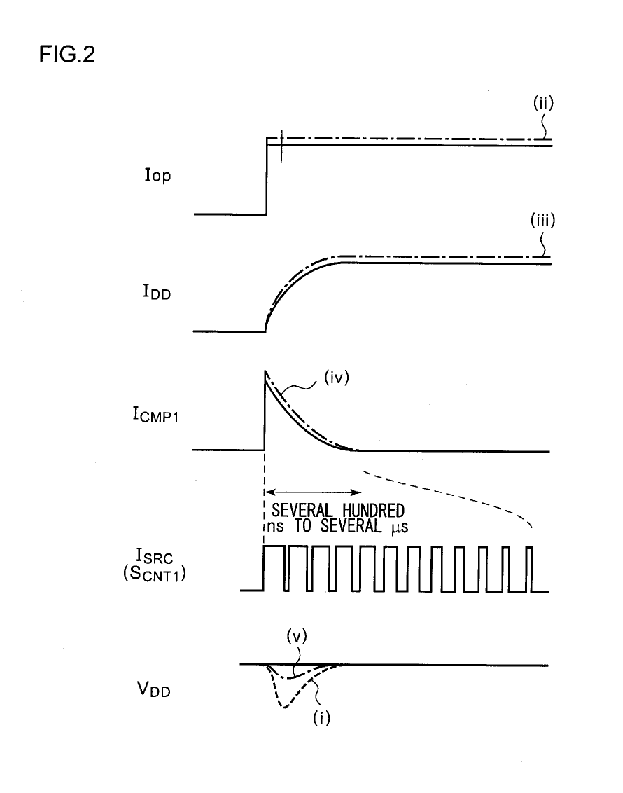

FIG. 2 is a waveform diagram which shows an example of the operating current I_{OP}, the power supply current I_{DD}, the source compensation current I_{CMP1}, and the source pulse current I_{SRC} subjected to pulse width modulation. Let us say that, when a certain test signal S_{TEST} is supplied to the DUT 1, the operating current I_{OP} of the DUT 1 rises in a stepwise manner. In response to the increase in the operating current I_{OP}, the power supply current I_{DD} is supplied from the main power supply 10. However, such a power supply current I_{DD} does not have an ideal step waveform because of the limited response speed. This leads to a shortfall in the current to be supplied to the DUT 1. As a result, if the compensation current I_{CMP1} is not supplied, the power supply voltage V_{DD} falls as indicated by the broken line (i).

The power supply compensation circuit 12 generates the source compensation current I_{CMP1} that corresponds to the difference between the operating current I_{OP} and the power supply current I_{DD}. The source compensation current I_{CMP1} is generated by convolution of the source pulse current I_{SRC} generated according to the control signal S_{CNT1}. The source compensation current I_{CMP1} is required to be at its maximum value immediately after the change in the operating current I_{OP}, and is required to gradually fall from its maximum value. Accordingly, the on time (duty ratio) of the source switch 12b is reduced over time, thereby generating the required source compensation current I_{CMP1}.

In a case in which all the channels of the test apparatus 2 operate in synchronization with a test rate, the period of the control signal S_{CNT1} matches the period (unit interval) of data to be supplied to the DUT 1, or a period obtained by multiplying or dividing the period of the data by an integer. For example, in a case in which the period of the control signal S_{CNT1} is set to 4 ns in a system in which the unit interval is 4 ns, the on period T_{ON} of each pulse included in the control signal S_{CNT1} can be adjusted in a range between 0 and 4 ns. The response speed of the main power supply 10 is on the order of several hundred ns to several μs. Thus, the waveform of the compensation current I_{CMP1} can be controlled by adjusting several hundred of the pulses included in the control signal S_{CNT1}. A method for deriving the control signal S_{CNT1} required to generate the source compensation current I_{CMP1} based upon the waveform thereof can be readily conceived by those skilled in this art, and accordingly, description thereof will be omitted.

Conversely, when the operating current I_{OP} is smaller than the power supply current I_{DD}, the power supply compensation circuit 12 generates a sink pulse current I_{SINK} so as to provide the sink compensation current I_{CMP2}, thereby drawing the excess current.

By providing such a power supply compensation circuit 12, such an arrangement is capable of compensating for a shortfall in the response speed of the main power supply 10, thereby maintaining the power supply voltage V_{DD} at a constant level as indicated by the solid line in FIG. 2.

The current that flows through an internal element (transistor or resistor) that is a component of the DUT 1 fluctuates due to process variation. That is to say, the operating current I_{DD} that actually flows in the DUT 1 is greater or smaller than the operating current I_{DD} predicted for a particular standard device. In general, it is the nature of the operating current I_{OP} of the DUT 1 that even if its amplitude level fluctuates due to process variation, its waveform is preserved. An increased operating current I_{OP} due to process variation is indicated by the line of dashes and dots (ii) in FIG. 2.

The output current I_{DD} of the main power supply 10 also changes as indicated by the line of dashes and dots (iii) in response to the operating current I_{OP} indicated by the line of dashes and dots (ii). Accordingly, the source compensation current I_{CMP1} to be supplied to the DUT 1 does not have the same waveform as that calculated for an ideal device, but has the waveform indicated by the line of dashes and dots (iv). If the source compensation current I_{CMP1} thus calculated as indicated by the solid line is supplied to such a DUT 1, the power supply voltage V_{DD} falls as indicated by the line of dashes and dots (v).

In order to solve such a problem, the voltage measurement unit 20 and the current adjustment unit 22 are provided. The test apparatus 2 executes a calibration step beforehand, before the test step for the DUT 1. In the calibration step, such an arrangement measures deviation in the operating current I_{OP} of the DUT 1 due to process variation. In a case in which the operation current I_{OP} of the DUT 1 is large, such an arrangement performs calibration so as to increase the compensation currents I_{CMP1} and I_{CMP2}. In a case in which the operation current I_{OP} of the DUT 1 is small, such an arrangement performs calibration so as to reduce the compensation currents I_{CMP1} and I_{CMP2}.

The above is the configuration of the test apparatus 2. Next, description will be made regarding its operation with reference to FIG. 2.

In the calibration step, the pattern generator PG outputs given test patterns S_{PTN1} through S_{PTN4} and the control patterns S_{PTN5} and S_{PTN6} that correspond to the test patterns S_{PTN1} through S_{PTN4}. In a case in which the operating current I_{OP} of the DUT 1 rises due to process variation, this leads to a shortfall in the compensation current I_{CMP1}, resulting in a problem of the power supply voltage V_{DD} being lower than the target value, as indicated by the broken line (v).

The voltage measurement unit 20 measures the power supply voltage V_{DD}. In the test step after the calibration, the current adjustment unit 22 adjusts the source compensation current I_{CMP1} to be generated according to the measured power supply voltage V_{DD}. Specifically, a reduction in the power supply voltage V_{DD} indicates a shortfall in the source compensation current I_{CMP1}. Accordingly, in this case, compensation should be performed so as to increase the source compensation current I_{CMP1}. Conversely, an increase in the power supply voltage V_{DD} indicates an excess amount of the source compensation current I_{CMP1}. Accordingly, in this case, compensation should be performed so as to reduce the source compensation current I_{CMP1}. The correction amount ΔI can be calculated based upon the amount of deviation in the power supply voltage V_{DD}.

The sink compensation current I_{CMP2} can be calculated in the same way. That is to say, in the calibration step, an increase in the power supply voltage V_{DD} indicates a shortfall in the sink compensation current I_{CMP2}. Accordingly, in this case, compensation should be performed so as to increase the sink compensation current I_{CMP2}. Conversely, a reduction in the power supply voltage V_{DD} indicates an excess amount of the sink compensation current I_{CMP2}. Accordingly, in this case, compensation should be performed so as to reduce the sink compensation current I_{CMP2}.

Next, description will be made regarding a compensation method for the compensation currents I_{CMP1} and I_{CMP2}. Description will be made below without distinguishing between the two compensation currents I_{CMP1} and I_{CMP2}. These two compensation currents I_{CMP1} and I_{CMP2} are collectively referred to as the “compensation current I_{CMP}”.

### [First Compensation Method]

The current adjustment unit 22 adjusts the amplitudes of the currents I_{SRC} and I_{SINK} according to the power supply voltage V_{DD} measured in the calibration step. For example, when the compensation current I_{CMP} in the initial state before the calibration step is 90% of a compensation current required to maintain the power supply voltage V_{DD} at a constant level, which has been obtained in the calibration step, the current adjustment unit 22 amplifies the amplitude of the pulse currents I_{SRC} and I_{SINK} with a gain of 1/0.9.

The source switch 12b and the sink switch 12c are each configured as a MOSFET. Accordingly, the degree of the on states of the source switch 12b and the sink switch 12c can be adjusted according to the gate voltages thereof, i.e., the voltage levels of the control signals S_{CNT1} and S_{CNT2}, respectively. Thus, by adjusting the output voltage levels (amplitude levels) of the source switch 12b and the sink switch 12c of the drivers DR₅ and DR₆, such an arrangement is capable of adjusting the amplitudes of the respective pulse currents I_{SRC} and I_{SINK}.

### [Second Compensation Method]

In a case in which the auxiliary power supply 12a is configured as a variable voltage source, the current adjustment unit 22 may control the amplitude of the source pulse current I_{SRC} by controlling the output voltage Vx of the auxiliary power supply 12a. Furthermore, by providing a voltage source on the ground terminal side of the sink switch 12c, and by controlling the output voltage of the voltage source thus provided, such an arrangement is capable of controlling the amplitude of the sink pulse current

### [Third Compensation Method]

In a case in which the auxiliary power supply 12a is configured as a current source, by controlling the output current of the auxiliary power supply 12a, the current adjustment unit 22 is capable of controlling the amplitude of the source current I_{SRC}. Furthermore, by providing a current source on a path of the sink switch 12c, and by controlling the output current of the current source thus provided, such an arrangement is capable of controlling the amplitude of the sink pulse current I_{SINK}.

### [Fourth Compensation Method]

The source switch 12b may include multiple MOSFETs arranged in parallel, and may be configured to permit adjustment of the number of MOSFETs that are controlled according to the control signal S_{CNT1}. That is to say, the source switch 12b is configured to allow the effective transistor size to be adjusted. The current adjustment unit 22 adjusts the number of transistors that compose the source switch 12b that is controlled according to the control signal S_{CNT1}. The sink switch 12c is configured and operated in the same way.

### [Fifth Compensation Method]

With the first through the fourth compensation methods, the compensation current I_{CMP} is adjusted by controlling the amplitudes of the source pulse current I_{SRC} and the sink pulse current I_{SINK}. In the fifth compensation method, the pulse widths of the source pulse current I_{SRC} and the sink pulse current I_{SINK} are adjusted.

For example, let us consider an arrangement in which the control signals S_{CNT1} and S_{CNT2} are each subjected to pulse width modulation. In this case, the current adjustment unit 22 may adjust the pulse widths of the control signals S_{CNT1} and S_{CNT2}. As a first method for adjusting the pulse widths of the control signals S_{CNT1} and S_{CNT2}, the control patterns S_{PTN5} and S_{PTN6} generated by the pattern generator PG may be adjusted. The control patterns S_{PTN5} and S_{PTN6} include timing setting data which respectively indicate the timings at which the on/off state of the source switch 12b and the on/off state of the sink switch 12c are to be switched. Thus, by changing, by means of the current adjustment unit 22, the timing setting data generated by the timing generator PG such that the pulse widths are adjusted, such an arrangement is capable of adjusting the pulse widths of the pulse currents I_{SRC} and I_{SINK}.

With such an arrangement, multiple control patterns having different pulse widths may be prepared for the respective control patterns S_{PTN5} and S_{PTN6}, and a pattern to be used may be selected from among the multiple patterns according to the measured power supply voltage V_{DD}. Alternatively, the pattern generator PG may adjust the timing setting data based upon the data received from the current adjustment unit 22.

### [Sixth Compensation Method]

With the fifth compensation method, the pulse widths of the pulse currents I_{SRC} and I_{SINK} are adjusted by adjusting the control patterns S_{PTN5} and S_{PTN6}. However, such modification of the control patterns S_{PTN5} and S_{PTN6} imposes a heavy burden on the software component or the hardware component. In order to solve such a problem, in the sixth compensation method, the pulse widths of the pulse currents I_{SRC} and I_{SINK} are modified without involving modification of the control patterns S_{PTN5} and S_{PTN6}.

For example, the timing generators TG of the interface circuits 4₅ and 4₆ are each configured to be capable of generating a set of predetermined timings. By making a combination of such multiple timings, such an arrangement is capable of generating a desired pulse width that corresponds to the control pattern S_{PTN5} or S_{PTN6}. Such a set of timings comprises integer multiples of the reference pulse width (obtained by multiplying the reference pulse width by 1, 2, 4, and so forth, and ½, ¼, and so forth), for example.

As an example, let us say that the reference pulse width is 100 ps and a timing set is prepared that comprises 400 ps, 200 ps, 100 ps, and 50 ps, and that the timing setting data of the control pattern S_{PTN5} comprises 4-bit data. The most significant bit of the timing setting data corresponds to 400 ps, and the least significant bit corresponds to 50 ps. When the timing setting data is set to [1111], the pulse width is set to 750 ps, and when the timing setting data is set to [0001], the pulse width is set to 50 ps.

With such an arrangement, the current adjustment unit 22 adjusts the pulse widths of the pulse currents I_{SRC} and I_{SINK} by adjusting the reference pulse width. For example, by changing the reference pulse width (reference timing) from 100 ps to 80 ps, such an arrangement is capable of reducing the pulse width by 20%, and by changing the reference pulse width (reference timing) from 100 ps to 120 ps, such an arrangement is capable of increasing the pulse width by 20%.

### [Seventh Compensation Method]

The timing generators TG of the interface circuits 4₅ and 4₆ are each configured to be capable of generating a set of predetermined timings. With such an arrangement, a set of multiple switchable timings is prepared for each timing generator TG.

For example, a first set is configured as (400 ps, 200 ps, 100 ps, 50 ps). A second set, where each timing is smaller than the corresponding timing in the first set, is configured as (300 ps, 150 ps, 75 ps, 25 ps). A third set, where each timing is greater than the corresponding timing in the first set, is configured as (500 ps, 300 ps, 150 ps, 75 ps).

When the first set is used, the pulse width that corresponds to the timing setting data [1111] is 750 ps. In contrast, when the second set is used, the pulse width that corresponds to the timing setting data [1111] is 550 ps, and when the third set is used, the pulse width that corresponds to the timing setting data [1111] is 1025 ps.

As described above, by switching the timing set to be used in the timing generators TG, such an arrangement is capable of modifying the pulse widths of the pulse currents I_{SRC} and I_{SINK} without involving modification of the control patterns S_{PTN5} and S_{PTN6}.

The above are specific examples of the compensation method. A desired combination of such compensation methods described above or below may be made and employed.

The correction amount for the pulse currents I_{SRC} and I_{SINK} obtained by the calibration, i.e., the correction amount for the compensation current I_{CMP}, is used in the test step even if a test pattern that differs from the test pattern SPTN used in the calibration step is supplied to the DUT 1.

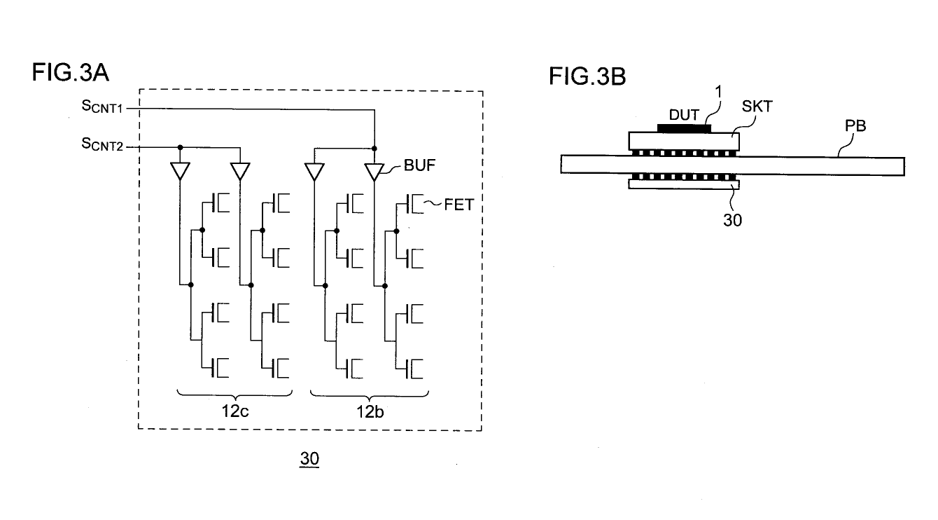

FIGS. 3A and 3B are diagrams showing a specific example configuration of the power supply compensation circuit 12. FIG. 3A is a diagram which shows an example configuration of the source switch 12b or the sink switch 12c. A DUT 1 of recent years is configured as a highly integrated circuit that requires a large operating current I_{OP}, and, accordingly, such a DUT includes multiple power supply terminals P1. A source switch 12b and a sink switch 12c each configured as a single MOSFET are not realistic for such a DUT 1. Instead, multiple small-size, high-speed MOSFETs are preferably connected in parallel, thereby allowing large pulse currents I_{SRC} and I_{SINK} to be generated. Such an arrangement is effective for providing minimum impedance of the power supply network.

Accordingly, as shown in FIG. 3A, a compensation circuit 30 (12b, 12c) is formed having a configuration in which multiple FETs are arranged over an area of the same extent as that of the chip or package of the DUT 1. The compensation circuit 30 may include a buffer BUF for every area comprising a predetermined number of multiple FETs. Each buffer is configured to receive the control signal S_{CNT}, and to drive the FETs.

FIG. 3B is a cross-sectional view of a test head of the test apparatus 2. An IC socket SKT is arranged on a performance board PB. The DUT 1 is mounted on the IC socket SKT. The compensation circuit 30 is arranged in a region on the back face of the performance board PB, opposite to the DUT 1. The compensation circuit may be configured as an IC, may be configured as a sub-module employing a printed-circuit board and discrete elements, or may be formed on the back face of the performance board.

Description has been made regarding the present invention with reference to the embodiments. The above-described embodiments have been described for exemplary purposes only, and are by no means intended to be interpreted restrictively. Rather, various modifications may be made by making various combinations of the aforementioned components or processes, which are also encompassed in the technical scope of the present invention. Description will be made below regarding such modifications.

### [First Modification]

Description has been made in the embodiment regarding an arrangement in which the pulse currents I_{SRC} and I_{SINK} are each subjected to pulse width modulation. However, the present invention is not restricted to such an arrangement. For example, the pulse currents I_{SRC} and I_{SINK} may be subjected to pulse density modulation. In this case, the pattern generator PG generates the control patterns PTN5 and PTN6 subjected to pulse density modulation so as to provide required compensation currents I_{CMP1} and I_{CMP2}. With such a first modification, the current adjustment unit 22 may adjust, according to the power supply voltage V_{DD}, the control patterns S_{PTN5} and S_{PTN6} generated by the pattern generator PG, thereby adjusting the pulse density. Alternatively, the aforementioned first through eighth modifications may be employed.

### [Second Modification]

Also, the pulse currents I_{SRC} and I_{SINK} may be subjected to pulse amplitude modulation according to a multi-valued signal. For example, in a case in which each driver DR is configured as a multi-valued driver, the amplitudes of the pulse currents I_{SRC} and I_{SINK} are changed according to the levels of the control signals S_{CNT1} and S_{CNT2}, respectively. The pattern generator PG generates the control patterns S_{PTN5} and S_{PTN6} so as to provide the required compensation currents I_{CMP1} and I_{CMP2}.

### [Third Modification]

As an arrangement configured to perform pulse amplitude modification on the pulse currents I_{SRC} and I_{SINK}/an arrangement may be made in which the source switch 12b and the sink switch 12c each have a configuration including multiple switches arranged in parallel, and a driver DR is assigned to each switch, so as to generate the control signal S_{CNT}. In this case, by changing the number of switches in the on state according to the control signal S_{CNT}, such an arrangement is capable of controlling the amplitudes of the respective pulse currents I_{SRC} and I_{SINK}.

The aforementioned first through eighth compensation methods can be applied to the second and third modifications.

### [Fourth Modification]

The pulse currents I_{SRC} and I_{SINK} may be subjected to delta-sigma modulation. In this case, the pattern generator PG generates the control patterns S_{PTN5} and S_{PTN6} subjected to delta-sigma modulation so as to provide the required compensation currents I_{CMP1} and I_{CMP2}.

With the fourth modification, according to the power supply voltage V_{DD}, the current adjustment unit 22 may adjust the pulse density of the pulses included in the control patterns S_{PTN5} and S_{PTN6} generated by the pattern generator PG. Alternatively, the aforementioned first through eighth compensation methods may be employed.

### [Fifth Modification]

The pulse currents I_{SRC} and I_{SINK} may be each subjected to pulse frequency modulation. In this case, the pattern generator PG generates the control patterns S_{PTN5} and S_{PTN6} subjected to pulse frequency modulation so as to provide the required compensation currents I_{CMP1} and I_{CMP2}.

### [Sixth Modification]

Description has been made in the embodiment regarding an arrangement in which the source switch 12b and the sink switch 12c are provided so as to generate the source compensation current I_{CMP1} and the sink compensation current I_{CMP2}. Also, only one of either the source switch 12b or the sink switch 12c may be provided.

The aforementioned embodiments and modifications can be summarized as follows. That is to say, in order to generate the required compensation current I_{CMP} in the test step, any one of the following modulations, or a combination of several of the following modulations, is applied to the pulse currents I_{SRC} and I_{SINK}:

(i) Pulse width modulation.

(ii) Pulse amplitude modulation.

(iii) Pulse density modulation.

(iv) Delta-sigma modulation.

(v) Pulse frequency modulation.

(vi) Other modulations that can be employed as an equivalent to any of the above.

Furthermore, in the calibration step, in order to adjust the compensation current I_{CMP}, any one of the parameters listed below, or a combination of several of the parameters listed below, is adjusted with respect to the pulse currents I_{SRC} and I_{SINK}.

(a) Pulse width.

(b) Pulse amplitude.

(c) Pulse density.

(d) Pulse frequency.

(e) Duty ratio.

Description has been made in the embodiment regarding an arrangement in which the compensation pulse currents I_{SRC} and I_{SINK} are adjusted based upon the power supply voltage V_{DD} measured in the calibration step. Also, the compensation pulse currents I_{SRC} and I_{SINK} may be adjusted by means of feedback based upon the power supply voltage V_{DD} measured in the test step.

The operating current I_{DD} of the DUT 1 also fluctuates according to the temperature. In order to solve such a problem, a temperature measurement unit configured to measure the temperature may be further provided, and the compensation pulse currents I_{SRC} and I_{SINK} may be adjusted so as to cancel out the fluctuation in the operating current I_{DD} that occurs according to the temperature.

It should be noted that description has been made in the embodiment regarding an arrangement configured to provide an ideal power supply environment having no fluctuation in the power supply voltage, i.e., having zero output impedance, using the compensation current I_{CMP}. However, the present invention is not restricted to such an arrangement. That is to say, the waveform of the compensation current I_{CMP} may be calculated so as to provided an intentional change in the power supply voltage, and the control pattern may be determined so as to provide such a compensation current waveform. Such an arrangement is capable of emulating a power supply environment as desired according to the control pattern. Furthermore, the aforementioned calibration step may be performed in a state in which the control pattern thus determined so as to provide an intentional change in the power supply voltage is generated. If there is a difference between fluctuation in the power supply voltage as measured and the design value when the control pattern and the test pattern assumed for a standard device are supplied to a given device under test, such an arrangement is capable of adjusting the compensation pulse currents I_{SRC} and I_{SINK} such that the difference becomes zero, thereby calibrating the compensation currents.

Also, the aforementioned calibration step may be performed in a state in which only the test pattern is supplied, but the control pattern is not supplied, i.e., in a state in which the power supply compensation circuit is not operated. In this case, the difference between fluctuation in the power supply voltage estimated when a test pattern is supplied to a standard device and that estimated when the same test pattern is supplied to a device under test represents a variation component of the operating current of the device under test that arises due to process variation. Thus, by adjusting the compensation pulse currents I_{SRC} and I_{SINK} based upon the power supply voltage measured for each device under test, such an arrangement is capable of calibrating the compensation current I_{CMP}.

While the preferred embodiments of the present invention have been described using specific terms, such description is for illustrative purposes only, and it is to be understood that changes and variations may be made without departing from the spirit or scope of the appended claims.

What is claimed is:

1. A test apparatus configured to test a device under test, the test apparatus comprising:
a main power supply configured to supply electric power to a power supply terminal of the device under test;
a power supply compensation circuit comprising a switch element configured to be controlled according to a control signal, and configured to generate a compensation pulse current when the switch element is turned on, and to inject the compensation pulse current thus generated into the power supply terminal via a path that differs from that of the main power supply, and/or to draw the compensation pulse current from the power supply current that flows from the main power supply to the device under test via a path that differs from that of the device under test;
a plurality of drivers, one of which is assigned to the switch element, and of which at least one other is assigned to at least one of the input/output terminals of the device under test;
a plurality of interface circuits provided to the respective drivers, each configured to shape an input pattern signal, and to output the pattern signal thus shaped to the corresponding driver;
a pattern generator configured to output a test pattern which specifies a test signal to be output from one driver assigned to the input/output terminal of the device under test to the interface circuit that corresponds to the driver, and to output a control pattern which specifies the control signal for the switch element to be output from one driver assigned to the switch element to the interface circuit that corresponds to the driver, the control pattern being determined according to the test pattern;
a voltage measurement unit configured to measure the power supply voltage in a state in which the pattern generator outputs the test pattern and the control pattern in a calibration step executed for each device under test; and
a current adjustment unit configured to adjust, for each device under test according to the power supply voltage measured for each device under test, the compensation pulse current to be generated in the test step after the calibration.

2. A test apparatus according to claim 1, wherein the control pattern is determined beforehand according to the test pattern such that the power supply voltage at the power supply terminal is maintained at a constant level in a state in which the test signal is supplied to a standard device under test,
and wherein the current adjustment unit is configured to adjust the compensation pulse current for each device under test such that the power supply voltage measured for each device under test is maintained at a constant level.

3. A test apparatus according to claim 1, wherein the control pattern is determined beforehand according to the test pattern such that a predetermined change in voltage occurs in the power supply voltage at the power supply terminal in a state in which the test signal is supplied to a standard device under test,
and wherein the current adjustment unit is configured to adjust the compensation pulse current for each device under test such that the change in the power supply voltage measured for each device under test approaches the predetermined change in voltage.

4. A test apparatus configured to test a device under test, the test apparatus comprising:
a main power supply configured to supply electric power to a power supply terminal of the device under test;
a power supply compensation circuit comprising a switch element configured to be controlled according to a control signal, and configured to generate a compensation pulse current when the switch element is turned on, and to inject the compensation pulse current thus generated into the power supply terminal via a path that differs from that of the main power supply, and/or to draw the compensation pulse current from the power supply current that flows from the main power supply to the device under test via a path that differs from that of the device under test;
a plurality of drivers, one of which is assigned to the switch element, and of which at least one other is assigned to at least one of the input/output terminals of the device under test;
a plurality of interface circuits provided to the respective drivers, each configured to shape an input pattern signal, and to output the pattern signal thus shaped to the corresponding driver;
a pattern generator configured to output a test pattern which specifies a test signal to be output from one driver assigned to the input/output terminal of the device under test to the interface circuit that corresponds to the driver, and to output a control pattern which specifies the control signal for the switch element to be output from one driver assigned to the switch element to the interface circuit that corresponds to the driver, the control pattern being determined according to the test pattern;
a voltage measurement unit configured to measure the power supply voltage in a state in which the pattern generator outputs the test pattern in a calibration step executed for each device under test; and
a current adjustment unit configured to adjust, for each device under test according to the power supply voltage measured for each device under test, the compensation pulse current to be generated in the test step after the calibration.

5. A test apparatus according to claim 1, wherein the current adjustment unit is configured to adjust the amplitude of the compensation pulse current according to the power supply voltage thus measured.

6. A test apparatus according to claim 5, wherein the degree of the on state of the switch element can be changed according to the voltage level of the control signal,
and wherein the current adjustment unit is configured to adjust the amplitude level of the driver according to the measured power supply voltage.

7. A test apparatus according to claim 5, wherein the power supply compensation circuit comprises:
an auxiliary power supply configured to generate a variable voltage; and
the switch element arranged between an output terminal of the auxiliary power supply and the power supply terminal,
wherein the current adjustment unit is configured to adjust the level of the variable voltage according to the power supply voltage thus measured.

8. A test apparatus according to claim 5, wherein the power supply compensation circuit comprises:
an auxiliary power supply; and
a plurality of switch elements arranged in parallel between an output terminal of the auxiliary power supply and the power supply terminal,
and wherein the current adjustment unit is configured to adjust, according to the measured power supply voltage, the number of switch elements that are controlled according to the control signal.

9. A test apparatus according to claim 1, wherein the current adjustment unit is configured to adjust the pulse width of the auxiliary pulse current according to the power supply voltage thus measured.

10. A test apparatus according to claim 9, wherein the interface circuit is configured to output a signal that corresponds to the control pattern, using a set of timings determined according to a reference pulse width,
and wherein the current adjustment unit is configured to adjust the reference pulse width according to the measured power supply voltage.

11. A test apparatus according to claim 9, wherein the interface circuit uses one from among the plurality of sets of timings determined beforehand to output, to the driver, a signal that corresponds to the control pattern,
and wherein the current adjustment unit is configured to switch the set of timings according to the measured power supply voltage.

12. A test apparatus according to claim 1, wherein the current adjustment unit is configured to adjust the pulse density of the compensation pulse current according to the power supply voltage thus measured.

13. A test apparatus according to claim 1, wherein the pattern generator has a plurality of control patterns determined such that they provide respective different amounts of compensation pulse currents for each test pattern,
and wherein the current adjustment unit is configured to switch the control pattern according to the measured power supply voltage.

14. A test apparatus according to claim 4, wherein the current adjustment unit is configured to adjust the amplitude of the compensation pulse current according to the power supply voltage thus measured.

15. A test apparatus according to claim 14, wherein the degree of the on state of the switch element can be changed according to the voltage level of the control signal,
and wherein the current adjustment unit is configured to adjust the amplitude level of the driver according to the measured power supply voltage.

16. A test apparatus according to claim 14, wherein the power supply compensation circuit comprises:
an auxiliary power supply configured to generate a variable voltage; and
the switch element arranged between an output terminal of the auxiliary power supply and the power supply terminal,
wherein the current adjustment unit is configured to adjust the level of the variable voltage according to the power supply voltage thus measured.

17. A test apparatus according to claim 14, wherein the power supply compensation circuit comprises:
an auxiliary power supply; and
a plurality of switch elements arranged in parallel between an output terminal of the auxiliary power supply and the power supply terminal,
and wherein the current adjustment unit is configured to adjust, according to the measured power supply voltage, the number of switch elements that are controlled according to the control signal.

18. A test apparatus according to claim 4, wherein the current adjustment unit is configured to adjust the pulse width of the auxiliary pulse current according to the power supply voltage thus measured.

19. A test apparatus according to claim 18, wherein the interface circuit is configured to output a signal that corresponds to the control pattern, using a set of timings determined according to a reference pulse width,
and wherein the current adjustment unit is configured to adjust the reference pulse width according to the measured power supply voltage.

20. A test apparatus according to claim 18, wherein the interface circuit uses one from among the plurality of sets of timings determined beforehand to output, to the driver, a signal that corresponds to the control pattern,
and wherein the current adjustment unit is configured to switch the set of timings according to the measured power supply voltage.

21. A test apparatus according to claim 4, wherein the current adjustment unit is configured to adjust the pulse density of the compensation pulse current according to the power supply voltage thus measured.

22. A test apparatus according to claim 4, wherein the pattern generator has a plurality of control patterns determined such that they provide respective different amounts of compensation pulse currents for each test pattern,
and wherein the current adjustment unit is configured to switch the control pattern according to the measured power supply voltage.
